(19) United States
(12) Patent Application Publication
(10) Pub. No.: US 2026/0052848 A1
(43) Pub. Date: Feb. 19, 2026

(54) Light Emitting Display Apparatus

(71) Applicant: LG Display Co., Ltd., Seoul (KR)

(72) Inventors: Jung Mo Cho, Paju-si (KR); Seung Kwang Roh, Paju-si (KR); Woo Chul Choi, Paju-si (KR); Sang Kyoung Moon, Paju-si (KR); Dong Il Choi, Paju-si (KR); Chi Hak Lee, Paju-si (KR); Bo A Jin, Paju-si (KR); Min Gue Shin, Paju-si (KR)

(21) Appl. No.: 19/269,805

(22) Filed: Jul. 15, 2025

(30) Foreign Application Priority Data
Aug. 14, 2024 (KR) 10-2024-0109164

(51) Int. Cl. H10K 59/122; H10K 50/17; H10K 59/131

(52) U.S. Cl. CPC H10K 59/122; H10K 50/171; H10K 59/131

(57) ABSTRACT

Disclosed is a light emitting display apparatus configured such that oxidation of an edge portion of an active area due to moisture and oxygen is prevented through a change in an edge structure of the active area and shrinkage of an emission layer of a light emitting diode is prevented, whereby the characteristics of the light emitting display apparatus, which is vulnerable to moisture and oxygen, are improved.

### CROSS-REFERENCE TO RELATED APPLICATION

This application claims the benefit of Republic of Korea Patent Application No. 10-2024-0109164, filed on Aug. 14, 2024, which is hereby incorporated by reference in its entirety.

### BACKGROUND

### Field of Technology

The present disclosure relates to a display apparatus, and more particularly to a light emitting display apparatus configured such that oxidation of an edge portion of an active area due to moisture and oxygen is prevented or at least reduced through a change in an edge structure of the active area and reliability of the light emitting display apparatus is improved.

### Discussion of the Related Art

In recent years, a self-emissive display apparatus has been considered as a competitive application in order to achieve miniaturization of the apparatus and vivid color display without necessity of a separate light source.

The self-emissive display apparatus includes a light emitting diode independently driven for each subpixel. Based on the material of the light emitting diode, the light emitting diode may be classified as an organic light emitting diode or an inorganic light emitting diode.

Meanwhile, a display apparatus having an organic light emitting diode has the problem that internal organic layers are vulnerable to moisture, etc., whereby reliability is reduced by moisture permeation, or an emission layer of the light emitting diode shrinks by ultra-violet (UV) irradiation.

### SUMMARY

Accordingly, the present disclosure is directed to a light emitting display apparatus that substantially obviates one or more problems due to limitations and disadvantages of the related art.

It is an object of the present disclosure to provide a light emitting display apparatus configured such that oxidation of an edge portion of an active area due to moisture and oxygen is prevented or at least reduced through a change in an edge structure of the active area and shrinkage of an emission layer of a light emitting diode is prevented, whereby the characteristics of the light emitting display apparatus, which is vulnerable to moisture and oxygen, are improved.

A light emitting display apparatus according to the present disclosure is configured such that the structure of an electron injection layer (EIL) is changed in corner regions and side regions of a display panel, whereby it is possible to prevent or at least reduce oxidation of the corner regions and the side regions due to moisture and oxygen and to prevent or at least reduce shrinkage of a light emitting diode.

In one embodiment, a light emitting display apparatus comprises: a substrate having an active area and a non-active area that is disposed at an edge of the light emitting display apparatus, the non-active area surrounding a center area of the active area, a corner region of the active area, and a side region of the active area that excludes the center area; a voltage line in the non-active area of the substrate; a bank having an emission open section in a pixel area of the active area and a bank open section on the voltage line; and an electron injection layer in the emission open section and the bank open section, the electron injection layer having different thicknesses in the center area of the active area and the corner region.

In one embodiment, a light emitting display apparatus comprises: a substrate having an active area and a non-active area that is disposed at an edge of the light emitting display apparatus, the non-active area surrounding a center area of the active area, a corner region of the active area, and a side region of the active area that excludes the center area; a voltage line in the non-active area of on the substrate; a thin-film transistor in a pixel area of the active area; an anode on the thin-film transistor in the pixel area, the anode electrically connected to the thin-film transistor; a connecting pattern on the voltage line, the connecting pattern electrically connected to the voltage line; a bank having an emission open section that exposes a portion of the anode and a bank open section that exposes a portion of the connecting pattern; an electron injection layer in the emission open section and the bank open section; and a cathode on the electron injection layer, wherein the electron injection layer has different thicknesses in the center area of the active area and the corner region.

In one embodiment, a display device comprises: a substrate having an active area and a non-active area that surrounds the active area, the active area including a center area and a corner area; a plurality of thin-film transistors including a first thin-film transistor and a second thin-film transistor; a first light-emitting diode in the center area that is electrically connected to the first thin-film transistor, the first light-emitting diode including a first anode electrode, a first organic emission layer on the first anode electrode that includes a first electron injection layer, and a cathode electrode on the first organic emission layer; and a second light-emitting diode in the corner area that is electrically connected to the second thin-film transistor, the second light-emitting diode including a second anode electrode, a second organic emission layer on the second anode electrode that includes a second electron injection layer, and a second cathode electrode on the second organic emission layer, wherein a thickness of the first electron injection layer is different than a thickness of the second electron injection layer.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a block diagram showing a display apparatus according to an embodiment of the present disclosure;

FIG. 2 is a circuit diagram showing a pixel circuit in the display apparatus according to an embodiment of the present disclosure;

FIG. 3 is a plan view of a display panel in the light emitting display apparatus according to an embodiment of the present disclosure;

FIG. 4 is a sectional view taken along line I-I′ of FIG. 3 according to an embodiment of the present disclosure;

FIGS. 5A and 5B are sectional views respectively showing part A and part B of FIG. 4 according to an embodiment of the present disclosure; and

FIGS. 6A to 6C are graphs showing UV transmittance, UV reflectance, and UV absorption of ytterbium (Yb), silver (Ag), and magnesium (Mg), which can be used as materials of an electron injection layer EIL according to an embodiment of the present disclosure for comparison.

### DETAILED DESCRIPTION

Hereinafter, embodiments of the present disclosure will be described with reference to the accompanying drawings. Throughout the specification, the same reference numerals designate substantially the same components.

In the following description, a detailed description of known technologies and configurations incorporated herein will be omitted when it may make the subject matter of the present disclosure rather unclear. In addition, names of components used in the following description are selected in consideration of ease in preparing the specification, and may be different from names of parts of an actual product.

In the drawings for explaining various embodiments of the present disclosure, for example, the illustrated shape, size, ratio, angle, and number are given by way of example, and thus, are not limitative of the present disclosure. Throughout the specification, the same reference numerals designate the same components.

Also, in describing the specification, a detailed description of known technologies will be omitted when it may make the subject matter of the present disclosure rather unclear.

The terms “comprises”, “includes”, and/or “has”, used in this specification, do not preclude the presence or addition of other elements unless used along with the term “only”. The singular forms are intended to include the plural forms as well, unless the context clearly indicates otherwise.

In the interpretation of components included in various embodiments of the present disclosure, the components are interpreted as including an error range even if there is no explicit description thereof.

In describing positional relationships in various embodiments of the present disclosure, for example, when the positional relationship between two parts is described using “on”, “above”, “below”, “beside”, or the like, one or more other parts may be located between the two parts unless the term “directly” or “closely” is used therewith

In describing temporal relationships in various embodiments of the present disclosure, for example, when the temporal relationship between two actions is described using “after”, “subsequently”, “next”, “before”, or the like, the actions may not occur in succession unless the term “immediately” or “directly” is used therewith.

In describing various embodiments of the present disclosure, although terms such as, for example, “first” and “second” may be used to describe various components, these terms are merely used to distinguish the same or similar components from each other. Therefore, in the specification, a component modified by “first” may be the same as a component modified by “second” within the technical scope of the present disclosure unless mentioned otherwise.

The respective features of various embodiments of the present disclosure may be partially or wholly coupled to and combined with each other, and various technical linkages therebetween and operation methods thereof are possible. The various embodiments may be performed independently of each other, or may be performed in association with each other.

Hereinafter, a light emitting display apparatus according to an embodiment of the present disclosure will be described with reference to the drawings.

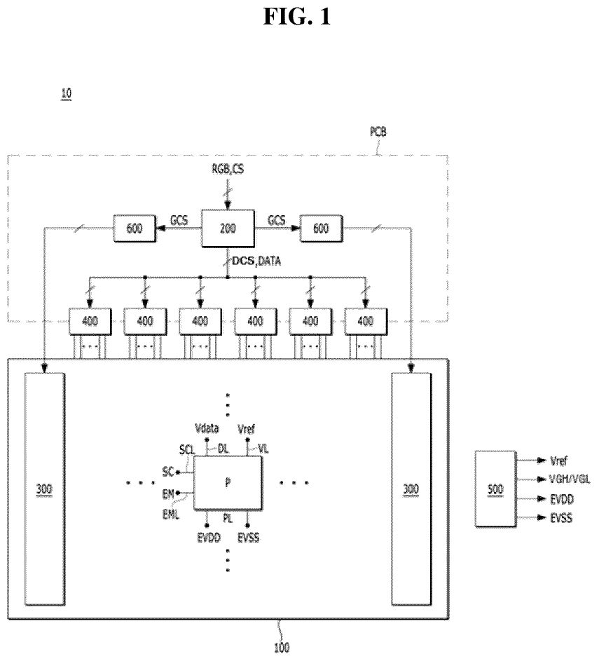

FIG. 1 is a schematic sectional view of a display apparatus according to an embodiment of the present disclosure.

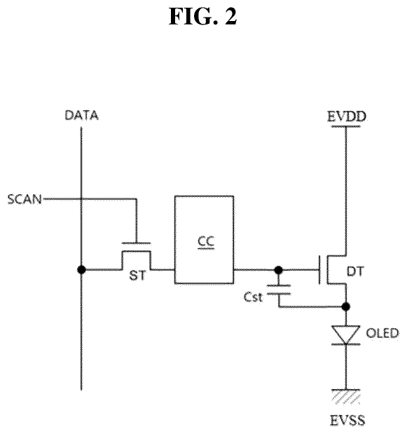

FIG. 2 is a circuit diagram showing a pixel circuit in the display apparatus according to an embodiment of the present disclosure.

As shown in FIG. 1, the display apparatus 10 according to the embodiment of the present disclosure includes a display panel 100 including a plurality of pixels P, a controller 200, a gate drive circuit 300 configured to supply a gate signal to each of the plurality of pixels P, a data drive circuit 400 configured to supply a data signal to each of the plurality of pixels P, a power supply unit 500 (e.g., a circuit) configured to supply power for operation to each of the plurality of pixels P, a level shifter 600 (e.g., a circuit) configured to adjust the potential of the gate signal applied to the gate drive circuit 300, and a sensing unit 700 (e.g., a circuit) configured to sense deterioration of the plurality of pixels P. Here, the controller 200, the gate drive circuit 300, the data drive circuit 400, and the sensing unit 700 may be collectively referred to as a control unit or control circuit.

The display panel 100 may include an active area AA (see FIG. 2) in which the pixels P are located and a non-active area NA in which a gate drive circuit 300 and a data drive circuit 400 are disposed, the non-active area being disposed so as to surround the active area AA. The gate drive circuit 300 may be disposed in the active area AA.

In the display panel 100, a plurality of gate lines (not shown) and a plurality of data lines DL intersect each other, each of the plurality of pixels P is connected to a corresponding one of the gate lines and a corresponding one of the data lines DL. Specifically, one pixel P receives a gate signal from the gate drive circuit 300 via the gate line, receives a data signal from the data drive circuit 400 via the data line DL, and receives a high-potential drive voltage EVDD and a low-potential drive voltage EVSS from the power supply unit 500 via a drive voltage line PL.

Here, the gate lines supply scan signals SC and emission control signals EM, and the data lines DL supply data voltages Vdata. In addition, according to various embodiments, the gate lines may include a plurality of scan lines SCL configured to supply scan signals SC and a plurality of emission control lines EML configured to supply emission control signals EM. In addition, each of the plurality of pixels P may further include a power line VL to receive a reference voltage Vref and an initialization voltage Vini.

Each thin-film transistor TFT constituting the pixel P may be implemented as an oxide TFT including an oxide semiconductor layer. The oxide TFT may be advantageous for large-area display panels 100 in consideration of electron mobility, process deviation, etc. The present disclosure is not limited thereto, and the semiconductor layer of the TFT may be made of amorphous silicon or polysilicon.

In addition, each pixel P includes a light emitting diode OLED and a pixel circuit configured to control the operation of the light emitting diode OLED. Here, the light emitting diode OLED may include an anode, a cathode, and an emission layer EML disposed between the anode and the cathode.

As shown in FIG. 2, each pixel P may include a switching transistor ST, a drive transistor DT, a compensation circuit CC, a light emitting diode OLED, and a storage capacitor Cst.

The light emitting diode OLED may be operated to emit light according to a drive current formed by the drive transistor DT.

The switching transistor ST may be switched such that a data signal supplied through the data line DL is stored in the storage capacitor Cst as a data voltage in response to the scan signal supplied through the gate line. The storage capacitor may maintain the data voltage for one frame.

The drive transistor DT may operate such that a constant drive current flows between the high-potential power line EVDD and the low-potential power line EVSS in response to the data voltage stored in the storage capacitor Cst.

The compensation circuit CC is a circuit configured to compensate for the threshold voltage of the drive transistor DT, and the compensation circuit CC may include one or more thin-film transistors and a capacitor. The configuration of the compensation circuit CC may vary greatly depending on a compensation method.

For example, the pixel P shown in FIG. 2 has a 2T (Transistor) 1C (Capacitor) structure including a switching transistor ST, a drive transistor DT, a storage capacitor Cst, and a light emitting diode OLED, but if the compensation circuit CC is added, the pixel may have various structures, such as 3T1C, 4T2C, 5T2C, 6T1C, 6T2C, 7T1C, 7T2C, and 8T1C structures.

The display panel 100 may be implemented as a non-transmissive display panel or a transmissive display panel. The transmissive display panel may be applied to a transparent display apparatus in which an image is displayed on the screen and a real object in the background is visible. The display panel 100 may be manufactured as a flexible display panel. The flexible display panel may be implemented as an organic light emitting display panel using a plastic substrate.

Each pixel P may be divided into a red pixel, a green pixel, and a blue pixel for color realization. Each pixel P may further include a white pixel. Each pixel P includes a pixel circuit.

Touch sensors may be disposed on the display panel 100. Touch input may be sensed using separate touch sensors or through the pixels P. The touch sensors may be implemented as on-cell or add-on type touch sensors that are disposed on the display panel or as in-cell type touch sensors that are embedded in the display panel 100.

The controller 200 processes image data RGB input from the outside so as to correspond to the size and resolution of the display panel 100 and supplies the same to the data drive circuit 400. The controller 200 generates a gate control signal GCS and a data control signal DCS using timing signals CS input from the outside, such as a dot clock signal CLK, a data enable signal DE, a horizontal synchronization signal Hsync, and a vertical synchronization signal Vsync. The generated gate control signal GCS and data control signal DCS are supplied to the gate drive circuit 300 and the data drive circuit 400, respectively, to control the gate drive circuit 300 and the data drive circuit 400.

The controller 200 may be coupled to various processors, such as a microprocessor, a mobile processor, an application processor, depending on a device in which the controller is mounted.

A host system may be any one of a television (TV) system, a set-top box, a navigation system, a personal computer (PC), a home theater system, a mobile device, a wearable device, and a vehicle system.

The controller 200 may control the operation timing of the display panel drive unit using a frame frequency of the input frame frequency×i (where i is a positive integer greater than 0) Hz obtained by multiplying the input frame frequency by i times. The input frame frequency is 60 Hz in a national television standards committee (NTSC) method and 50 Hz in a phase-alternating line (PAL) method.

The controller 200 generates a signal to enable the pixel P to be driven at various refresh rates. That is, the controller 200 generates signals associated with driving such that the pixel P may be driven in a variable refresh rate (VRR) mode or to switch between a first refresh rate and a second refresh rate. For example, the controller 200 may drive the pixel P at various refresh rates by simply changing the speed of a clock signal, generating a synchronizing signal to create a horizontal blank or a vertical blank, or driving the gate drive circuit 300 in a mask manner.

Based on the timing signal CS received from the host system, the controller 200 generates a gate control signal GCS for controlling the operation timing of the gate drive circuit 300 and a data control signal DCS for controlling the operation timing of the data drive circuit 400. The controller 200 controls the operation timing of the display panel drive unit to synchronize the gate drive circuit 300 and the data drive circuit 400.

The data drive circuit 400 receives the image data DATA and the data control signal DCS from the controller 200. The data drive circuit 400 converts the image data DATA into a gamma-compensated voltage to generate a data voltage Vdata in response to the data control signal DCS from the controller 200, and supplies the data voltage Vdata to the data lines DL of the display panel 100 in synchronization with the scan signal SC. The data drive circuit 400 may be connected to the data lines of the display panel 100 through a chip on glass (COG) or tape automated lamination (TAB) process.

The gate drive circuit 300 is operated according to the gate control signal GCS input from the level shifter 600 to generate a gate signal, and sequentially supplies the gate signal to gate lines GL. The gate drive circuit 300 may be formed directly on a lower substrate of the display panel 100 using a gate driver in panel (GIP) method. The gate drive circuit 300 may be formed in the active area AA of the display panel 100 in which the screen is displayed, or may be formed in the non-active area NA outside the active area AA. The non-active area NA may include a bezel area, or may be the same as the bezel area. In the GIP method, the level shifter 600 may be mounted on a printed circuit board (PCB) together with the controller 200.

The power supply unit 500 generates direct current (DC) power required to drive a pixel array of the display panel 100 and a display panel driver using a DC-DC converter. The DC-DC converter may include a charge pump, a regulator, a buck converter, and a boost converter. The power supply unit 500 receives a DC input voltage from the host system (not shown) to generate DC voltages such as gate-on voltages VGL and VEL, gate-off voltages VGH and VEH, a high-potential drive voltage EVDD, and a low-potential drive voltage EVSS. The gate-on voltages VGL and VEL and the gate-off voltages VGH and VEH are supplied to the level shifter and the gate drive circuit 300. The high-potential drive voltage EVDD and the low-potential drive voltage EVSS are supplied to the pixels P in common.

The level shifter 600 boosts a transistor-transistor-logic (TTL) level voltage of the gate control signal GCS input from the controller 200 to a gate high voltage VGH and a gate low voltage VGL that can drive the TFT formed on the display panel 100 and supplies the same to the gate drive circuit 300. The gate control signal GCS may include a start signal and a clock signal. The plurality of pixels P of the display panel 100 may include at least a first pixel, a second pixel, and a third pixel. The first pixel, the second pixel, and the third pixel may emit light of different colors. For example, the first pixel may be a red pixel, the second pixel may be a green pixel, and the third pixel may be a blue pixel.

The plurality of pixels P may have the same size or different sizes. The first, second, and third pixels may be designed so as to have different sizes taking into account the lifetime of the light emitting diode OLED included in each of the first, second, and third pixels or the color balance.

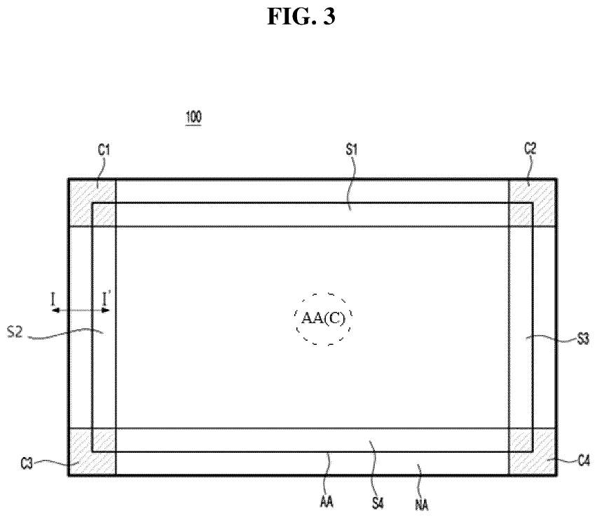

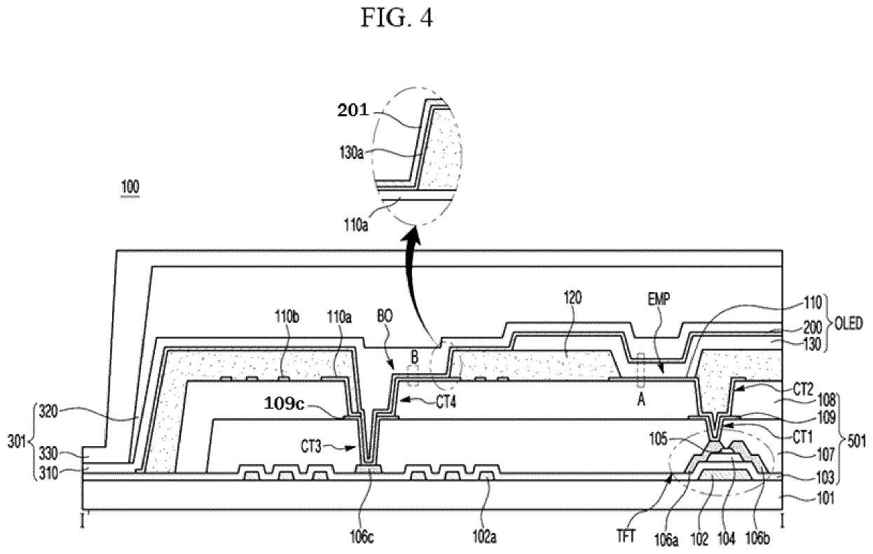

FIG. 3 is a plan view of the display panel in the light emitting display apparatus according to an embodiment of the present disclosure, and FIG. 4 is a sectional view taken along line I-I′ of FIG. 3 according to an embodiment of the present disclosure.

As shown in FIG. 3, in the light emitting display apparatus according to the present disclosure, the display panel 100 includes an active area AA configured to display an image and a non-active area NA disposed at an edge of the display panel so as to surround the active area AA in a plan view of the display panel 100.

The active area AA may be divided into a center area AA (C) and a peripheral area. The peripheral area of the active area AA and the non-active area NA may be divided into four corner regions C1 to C4 and four side regions S1 to S4.

In the active area AA, a plurality of pixels are disposed in a matrix form, and a light emitting diode OLED and a drive circuit configured to drive the light emitting diode OLED are disposed at each pixel.

Each pixel may include a switching transistor ST, a drive transistor DT, a compensation circuit CC, a light emitting diode OLED, and a storage capacitor Cst, as shown in FIG. 2.

As shown in FIG. 4, the sectional structure of the display panel according to the embodiment of the present disclosure may be mainly divided into a substrate 101, a thin-film transistor array substrate 501, and a light emitting diode OLED. The thin-film transistor array substrate 501 may include a thin-film transistor configured to drive the light emitting diode OLED, various signal lines, and a power supply line.

First, the configuration of the thin-film transistor array substrate 501 will be described.

The thin-film transistor TFT may be disposed in the active area AA on the substrate 101, which is divided into the active area AA and the non-active area NA. The thin-film transistor TFT includes a gate electrode 102 disposed on the substrate 101, a gate insulating film 103 disposed on the entire surface of the substrate including the gate electrode 102, a semiconductor layer 104 disposed on the gate insulating film 103 so as to overlap the gate electrode 102, and a source electrode 106a and a drain electrode 106b connected to both sides of the semiconductor layer 104.

The gate insulating film 103 is provided between the gate electrode 102 and the semiconductor layer 104, and a channel protection layer 105 is provided above a channel of the semiconductor layer 104 to protect the channel of the semiconductor layer 104 when the source electrode 106a and the drain electrode 106b are connected to the semiconductor layer 104. The channel protection layer 105 is between the semiconductor layer 104 and the source and drain electrodes 106a, 106b.

The semiconductor layer 104 may include at least one of an oxide semiconductor layer, a polysilicon layer, and an amorphous silicon layer, and may be formed so as to have two or more layers including the same material or different materials depending on circumstances.

The gate electrode 102 may be made of a metal material. For example, the gate electrode 102 may have a single-layer or multi-layer structure including any one of molybdenum (Mo), aluminum (Al), chromium (Cr), gold (Au), titanium (Ti), nickel (Ni), neodymium (Nd), and copper (Cu), or an alloy thereof; however, the present disclosure is not limited thereto.

Signal lines 102a and a first power voltage line 106c may be disposed on the substrate 101 in the non-active area NA. The signal lines 102a may be gate lines (scan signal lines) configured to provide scan signals to the respective pixels, and the first power voltage line 106c may be a power line configured to supply a common voltage to the cathode of the light emitting diode OLED.

The signal lines 102a may be disposed on the substrate 101 and covered by the gate insulating film 103, and the first power voltage line 106c may be disposed on the gate insulating film 103. The signal lines 102a may be made of the same material as the gate electrode 102, and the first power voltage line 106c may be made of the same material as the source electrode 106a and the drain electrode 106b.

First and second planarization films 107 and 108 may be disposed over the active area AA and the non-active area NA so as to cover the thin-film transistor, the signal lines 102a, and the first power voltage line 106c.

A first contact hole CT1 may be formed in the first planarization layer 107 to expose a portion of the source electrode 106a of the thin-film transistor, and a first connecting metal pattern 109 may be provided between the first planarization layer 107 and the second planarization layer 108 so as to be electrically connected to the source electrode 106a via the first contact hole CT1.

In addition, a third contact hole CT3 may be formed in the first planarization layer 107 to expose a portion of the first power voltage line 106c in the non-active area NA. A second connecting metal pattern 109c may be provided between the first planarization layer 107 and the second planarization layer 108 so as to be electrically connected to the first power voltage line 106c via the third contact hole CT3. The first connecting metal pattern 109 and the second connecting metal pattern 109c may be made of the same material and may be disposed on the same layer.

Next, the configuration of the light emitting diode OLED will be described.

A second contact hole CT2 may be formed in the second planarization film 108 such that a portion of the first connecting metal pattern 109 is exposed. An anode 110 of the light emitting diode OLED may be disposed on the second planarization film 108 so as to be electrically connected to the first connecting metal pattern 109 via the second contact hole CT2.

In addition, a fourth contact hole CT4 may be formed in the second planarization film 108 such that a portion of the second connecting metal pattern 109c is exposed in the non-active area NA. A connecting pattern 110a and an anode dummy pattern 110b may be provided on the second planarization layer 108 so as to be electrically connected to the second connecting metal pattern 109c via the fourth contact hole CT4.

The connecting pattern 110a, the anode 110, and the anode dummy pattern 110b may be made of the same material and may be formed through the same process. The connecting pattern 110a may be provided for electrical connection with the first power voltage line 106c, and the anode dummy pattern 110b may be a pattern for inspection of the area surrounding the active area AA or may be provided for connection with other signals. In some cases, the second connecting metal pattern 109c may be omitted, such that the connecting pattern 110a may be directly connected to the first power voltage line 106c.

A bank 120 may be disposed on the second planarization film 108 including the connecting pattern 110a, the anode 110, and the anode dummy pattern 110b.

The bank 120 may have a bank open section BO configured to expose the connecting pattern 110a provided in the non-active area NA along the edge of the active area AA of the substrate 101 and an emission open section EMP configured to expose the anode 110 of each pixel in the active area AA.

A first organic emission layer 130 may be disposed on the anode 110 of the emission open section EMP and a second organic emission layer 130a may be disposed on the connecting pattern 110a of the bank open section BO. The stacking structures of the first organic emission layer 130 disposed on the anode 110 of the emission open section EMP and the second organic emission layer 130a disposed on the connecting pattern 110a of the bank open section BO may be different. The structures will be described later in more detail with reference to FIG. 3.

A cathode 201 may be disposed on the entire surface of the substrate on which the bank 200 and the first and second organic emission layers 130 and 130a are formed. The cathode 201 overlaps the anode 110 in the state in which the first organic emission layer 130 is interposed therebetween in the active area AA, and is electrically connected to the connecting pattern 110a in the non-active area NA.

An encapsulation layer 301 configured to protect the light emitting diode OLED is formed on the cathode 201. As an example, the encapsulation layer 301 may be configured such that inorganic encapsulation layers 310 and 330 and an organic encapsulation layer 320 are alternately disposed. The inorganic encapsulation layers 310 and 330 may be formed so as to be adjacent to or to extend to the edge of the substrate 101 than the organic encapsulation layer 320 to more effectively prevent the penetration of moisture from the side.

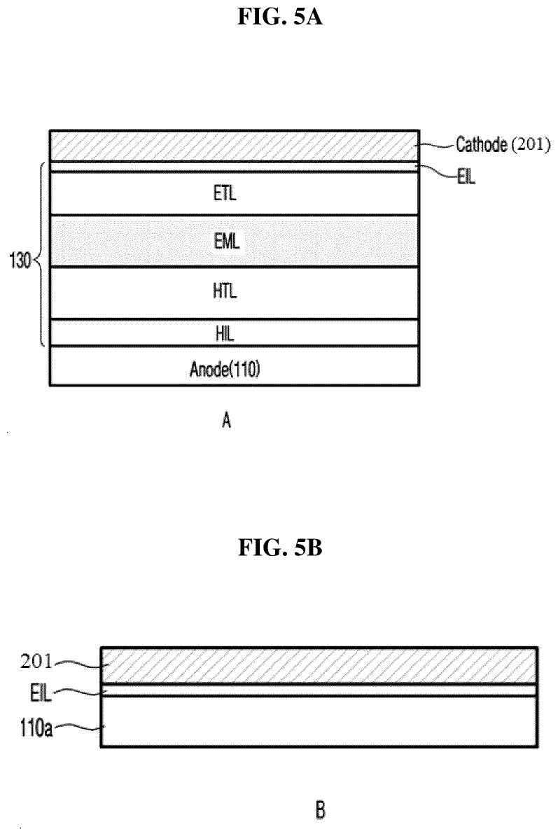

FIGS. 5A and 5B are sectional views respectively showing part A and part B of FIG. 4 according to an embodiment of the present disclosure.

As shown in FIG. 5A, the light emitting diode OLED disposed in the active area includes a first organic emission layer 130 between the anode 110 and the cathode 201, which are opposite each other. The first organic emission layer 130 may include a hole injection layer HIL, a hole transport layer HTL, an emission layer EML, an electron transport layer ETL, and an electron injection layer EIL sequentially stacked on the anode 110. The electron injection layer EIL may be relatively thin.

The second organic emission layer 130a disposed on the connecting pattern 110a of the bank open section BO in the non-active area NA may include a hole injection layer HIL, a hole transport layer HTL, an electron transport layer ETL, and an electron injection layer EIL.

However, as shown in FIG. 5B, the second organic emission layer 130a may include only the electron injection layer EIL in order to reduce the contact resistance between the connecting pattern 110a and the cathode 201. That is, the second organic emission layer 130a may lack (e.g., does not include) a hole injection layer HIL, a hole transport layer HTL, and an electron transport layer ETL.

In the light emitting display panel described with reference to FIG. 4, when the bank open section BO and the emission open section EMP are formed in the bank 120, moisture may remain in the bank open section BO and the emission open section EMP and may permeate through the bank 120.

In addition, when the encapsulation layer 301 is formed after the first or second organic emission layer 130 or 130a is formed in the bank open section BO or the emission open section EMP, the first or second organic emission layer 130 or 130a may be outgassed as a result of reaction of a p-type dopant in the hole injection layer HIL or the hole transport layer HTL by UV irradiation, which may cause the light emitting diode OLED to shrink. Consequently, the characteristics of the light emitting diode OLED may change.

However, since the electron injection layer EIL is disposed in the bank open section BO and the emission open section EMP, it is possible to prevent the phenomenon that some moisture remains in the bank open section BO and the emission open section EMP due to moisture from the outside or during cooling and permeates through the bank 120.

In addition, since the electron injection layer EIL is disposed in the bank open section BO and the emission open section EMP, it is possible to prevent shrinkage of the light emitting diode OLED due to exposure to external light (UV) or heat.

This is due to the following reasons.

The electron injection layer EIL is a component including inorganic matter or an inorganic compound and a metal. For example, the electron injection layer EIL may include at least one of lithium fluoride (LiF), ytterbium (Yb), silver (Ag), and magnesium (Mg), and may also include some ingredients of the cathode 201. Meanwhile, the electron injection layer EIL has the main function of facilitating the injection of electrons from the cathode 201 into the first organic emission layer 130 in the light emitting diode OLED, and to this end, the electron injection layer may include a metal having low interfacial resistance with the first organic emission layer 130 and a low work function.

In addition, the electron injection layer EIL may be formed so as not to be too thick such that the electrical connection resistance between the cathode 201 and the connecting pattern 110a disposed thereunder does not increase.

For example, as shown in [Formula 1], if the electron injection layer EIL includes lithium fluoride (LiF) and moisture enters the bank open section BO or the emission open section EMP, lithium (Li) and fluorine (F) may be separated from each other, lithium (Li) and hydroxide may react with each other, and hydrogen fluoride (HF) may be released to the outside, thereby preventing the effect of moisture.

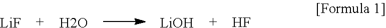

In addition, if the electron injection layer EIL includes ytterbium (Yb), UV irradiated to the first or second organic emission layer 130 or 130a may be blocked, thereby preventing shrinkage of the light emitting diode OLED.

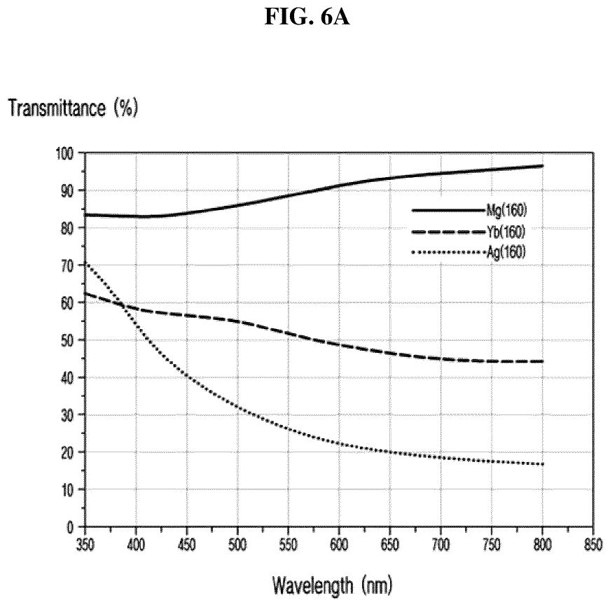

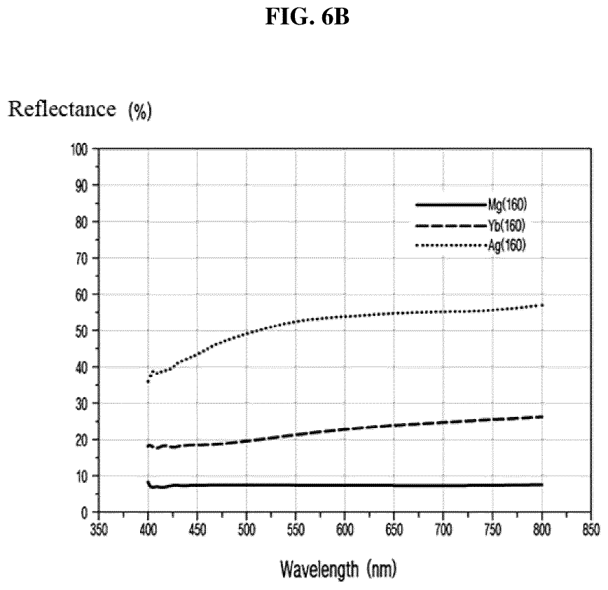

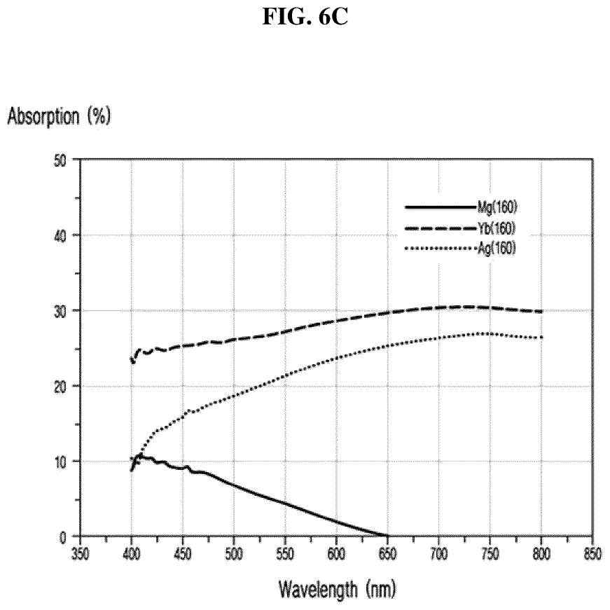

FIGS. 6A to 6C are graphs showing UV transmittance, UV reflectance, and UV absorption of ytterbium (Yb), silver (Ag), and magnesium (Mg), which can be used as materials of the electron injection layer EIL according to the present disclosure for comparison.

That is, FIG. 6A is a graph showing the transmittance of ytterbium (Yb), silver (Ag), and magnesium (Mg) for comparison, FIG. 6B is a graph showing the reflectance of ytterbium (Yb), silver (Ag), and magnesium (Mg) for comparison, and FIG. 6C is a graph showing the absorption of ytterbium (Yb), silver (Ag), and magnesium (Mg) for comparison. In FIGS. 6A to 6C, the thicknesses of ytterbium (Yb), silver (Ag), and magnesium (Mg) are all the same.

As can be seen from FIG. 6A, magnesium (Mg) has the highest transmittance, followed by ytterbium (Yb) and silver (Ag).

As can be seen from FIG. 6B, silver (Ag) has the highest reflectivity, followed by ytterbium (Yb) and magnesium (Mg).

In addition, as can be seen from FIG. 6C, ytterbium (Yb) has the highest absorption, followed by silver (Ag) and magnesium (Mg).

Since ytterbium (Yb) has the highest absorption of UV, as described above, even if UV is radiated to the first or second organic emission layer 130 or 130a when the encapsulation layer 301 is formed, the radiation of UV to the first or second organic emission layer 130 or 130a may be blocked when the encapsulation layer 301 is formed if the electron injection layer EIL includes ytterbium (Yb).

Meanwhile, as described with reference to FIG. 3, the light emitting display panel 100 according to the present disclosure may be divided into an active area AA and a non-active area NA disposed at an edge of the light emitting display apparatus so as to surround the active area AA. In one embodiment, the active area AA may be divided into a center area AA (C) and a peripheral area, and the peripheral area of the active area AA may be divided into four corner regions C1 to C4 and four side regions S1 to S4. Each side region S1 to S4 is disposed between a pair of corner regions. For example, side region S1 is disposed between corner regions C1 and C2, side region S2 is disposed between corner regions C1 and C3, side region S3 is disposed between corner regions C2 and C4, and side region S4 is disposed between corner regions C3 and C4.

Here, the four corner regions C1 to C4 are most likely to be moisturized because the four corner regions have the largest sections exposed to the outside. In addition, the four side regions S1 to S4 have smaller sections exposed to the outside than the four corner regions C1 to C4, whereby the four side regions are exposed to external light (UV) or heat rather than being moisturized, and therefore there is a high probability that the light emitting diode OLED will shrink.

Therefore, an electron injection layer EIL having a ratio of ytterbium (Yb) to lithium fluoride (LiF) of 2:1 is disposed in the center area AA (C) of the active area AA.

An electron injection layer EIL having a ratio of ytterbium (Yb) to lithium fluoride (LiF) of 1:2 or 1:3 is disposed in each of the four corner regions C1 to C4. The thickness of the electron injection layer EIL disposed in each of the four corner regions C1 to C4 is greater than the thickness of the electron injection layer EIL disposed in the center area AA (C) of the active area AA. For example, the electron injection layer EIL disposed in the center area AA (C) of the active area AA may have a thickness of about 30 Å, and the electron injection layer EIL disposed in each of the four corner regions C1 to C4 may have a thickness of about 40 to 50 Å. Thus, an electron injection layer EIL of a first light-emitting diode OLED in the center area AA (C) is thinner than an electron injection layer EIL of a second light-emitting diode OLED that is disposed on one of the four corner regions C1 to C4. This results in the organic emission layer of the second light-emitting diode OLED being thicker than the organic emission layer of the first light-emitting diode OLED since the electron injection layer EIL of the second light-emitting diode OLED is thicker than the electron injection layer EIL of the first light-emitting diode OLED.

In addition, an electron injection layer EIL having a ratio of ytterbium (Yb) to lithium fluoride (LiF) of 3:1 may be disposed in each of the four side regions S1 to S4. The thickness of the electron injection layer EIL disposed in each of the four side regions S1 to S4 is equal to the thickness of the electron injection layer EIL disposed in the center area AA (C) of the active area AA. Thus, a thickness of an electron injection layer EIL of the first light-emitting diode OLED in the center area AA (C) is the same as a thickness of an electron injection layer EIL of a third light-emitting diode OLED that is disposed on one of the four side regions S1 to S4.

According to the present disclosure, as described above, the material structure and thickness of the electron injection layer may be changed in the corner regions and the side regions of the display panel, whereby it is possible to prevent oxidation of the corner regions and the side regions due to moisture and oxygen and to prevent shrinkage of the light emitting diode.

A light emitting display apparatus according to various embodiments of the present disclosure may be described as follows.

In one embodiment, a light emitting display apparatus comprises: a substrate having an active area and a non-active area that is disposed at an edge of the light emitting display apparatus, the non-active area surrounding a center area of the active area, a corner region of the active area, and a side region of the active area that excludes the center area; a voltage line in the non-active area of the substrate; a bank having an emission open section in a pixel area of the active area and a bank open section on the voltage line; and an electron injection layer in the emission open section and the bank open section, the electron injection layer having different thicknesses in the center area of the active area and the corner region.

In one embodiment, a thickness of the electron injection layer in the corner region is thicker than a thickness of the electron injection layer in the center area of the active area.

In one embodiment, the thickness of the electron injection layer in the center area of the active area is the same as a thickness of the electron injection layer in the side region.

In one embodiment, the electron injection layer comprises ytterbium and lithium fluoride and the electron injection layer in the center area of the active area has a ratio of ytterbium to lithium fluoride of 2:1.

In one embodiment, the electron injection layer comprises ytterbium and lithium fluoride and the electron injection layer in the corner region has a ratio of ytterbium to lithium fluoride of 1:2 or 1:3.

In one embodiment, the electron injection layer comprises ytterbium and lithium fluoride and the electron injection layer in the side region has a ratio of ytterbium to lithium fluoride of 3:1.

In one embodiment, a light emitting display apparatus comprises: a substrate having an active area and a non-active area that is disposed at an edge of the light emitting display apparatus, the non-active area surrounding a center area of the active area, a corner region of the active area, and a side region of the active area that excludes the center area; a voltage line in the non-active area of on the substrate; a thin-film transistor in a pixel area of the active area; an anode on the thin-film transistor in the pixel area, the anode electrically connected to the thin-film transistor; a connecting pattern on the voltage line, the connection pattern electrically connected to the voltage line; a bank having an emission open section that exposes a portion of the anode and a bank open section that exposes a portion of the connecting pattern; an electron injection layer in the emission open section and the bank open section; and a cathode on the electron injection layer, wherein the electron injection layer has different thicknesses in the center area of the active area and the corner region.

In one embodiment, a thickness of the electron injection layer in the corner region is thicker than a thickness of the electron injection layer in the center area of the active area.

In one embodiment, the thickness of the electron injection layer in the center area is the same as a thickness of the electron injection layer in the side region.

In one embodiment, the electron injection layer comprises ytterbium and lithium fluoride and the electron injection layer in the center area of the active area has a ratio of ytterbium to lithium fluoride of 2:1.

In one embodiment, the electron injection layer comprises ytterbium and lithium fluoride and the electron injection layer in the corner region has a ratio of ytterbium to lithium fluoride of 1:2 or 1:3.

In one embodiment, the electron injection layer comprises ytterbium and lithium fluoride and the electron injection layer in the side region has a ratio of ytterbium to lithium fluoride of 3:1.

In one embodiment, the light emitting display apparatus further comprises a hole injection layer, a hole transport layer, an emission layer, and an electron transport layer between the anode and the electron injection layer in the emission open section.

In one embodiment, the voltage line and the thin-film transistor are on a same layer and further comprises a first planarization layer and a second planarization layer between the voltage line and the thin-film transistor and the anode, a first connecting metal pattern between the first planarization layer and the second planarization layer that electrically connects the thin-film transistor and the anode, and a second connecting metal pattern between the first planarization layer and the second planarization layer that electrically connects the voltage line and the connecting pattern.

In one embodiment, the light emitting display apparatus further comprises an encapsulation layer on the cathode.

In one embodiment, a display device comprises: a substrate having an active area and a non-active area that surrounds the active area, the active area including a center area and a corner area; a plurality of thin-film transistors including a first thin-film transistor and a second thin-film transistor; a first light-emitting diode in the center area that is electrically connected to the first thin-film transistor, the first light emitting diode including a first anode electrode, a first organic emission layer on the first anode electrode that includes a first electron injection layer, and a cathode electrode on the first organic emission layer; and a second light-emitting diode in the corner area that is electrically connected to the second thin-film transistor, the second light emitting diode including a second anode electrode, a second organic emission layer on the second anode electrode that includes a second electron injection layer, and a second cathode electrode on the second organic emission layer, wherein a thickness of the first electron injection layer is different than a thickness of the second electron injection layer.

In one embodiment, the thickness of the second electron injection layer is thicker than the thickness of the first electron injection layer.

In one embodiment, the plurality of thin-film transistors includes a third thin-film transistor and further comprises a third light-emitting diode that is electrically connected to the third thin-film transistor and disposed in a side area of the active area that is between a pair of corner areas of the active area, the third light-emitting diode including a third anode electrode, a third organic emission layer on the third anode electrode that includes a third electron injection layer, and a third cathode electrode on the third organic emission layer, wherein a thickness of the first electron injection layer is the same as a thickness of the third electron injection layer.

In one embodiment, the first electron injection layer comprises ytterbium and lithium fluoride having a ratio of ytterbium to lithium fluoride of 2:1 and the second electron injection layer comprises ytterbium and lithium fluoride having a ratio of ytterbium to lithium fluoride of 1:2 or 1:3.

In one embodiment, the third electron injection layer comprises ytterbium and lithium fluoride having a ratio of ytterbium to lithium fluoride of 3:1.

In one embodiment, the display device further comprises a voltage line in the non-active area and a third organic emission layer that overlaps the voltage line in the non-active area, the third organic emission layer having a third electron injection layer but not including a hole injection layer, a hole transport layer, an emission layer, and an electron transport layer.

As is apparent from the above description, the light emitting display apparatus according to the present disclosure has the following effects.

First, the material structure and thickness of the electron injection layer EIL may be changed in the corner regions and the side regions of the display panel, whereby it is possible to prevent oxidation of the corner regions and the side regions due to moisture and oxygen.

Second, the material structure and thickness of the electron injection layer EIL may be changed in the corner regions and the side regions of the display panel, whereby it is possible to prevent shrinkage of the light emitting diode.

It will be apparent to those skilled in the art that the present disclosure described above is not limited to the above embodiments and the accompanying drawings and that various substitutions, modifications, and variations may be made without departing from the technical idea of the present disclosure.

What is claimed is:

1. A light emitting display apparatus comprising:
a substrate having an active area and a non-active area that is disposed at an edge of the light emitting display apparatus, the non-active area surrounding a center area of the active area, a corner region of the active area, and a side region of the active area that excludes the center area;
a voltage line in the non-active area of the substrate;
a bank having an emission open section in a pixel area of the active area and a bank open section on the voltage line; and
an electron injection layer in the emission open section and the bank open section, the electron injection layer having different thicknesses in the center area of the active area and the corner region.

2. The light emitting display apparatus according to claim 1, wherein a thickness of the electron injection layer in the corner region is thicker than a thickness of the electron injection layer in the center area of the active area.

3. The light emitting display apparatus according to claim 2, wherein the thickness of the electron injection layer in the center area of the active area is a same as a thickness of the electron injection layer in the side region.

4. The light emitting display apparatus according to claim 1, wherein the electron injection layer comprises ytterbium and lithium fluoride and the electron injection layer in the center area of the active area has a ratio of ytterbium to lithium fluoride of 2:1.

5. The light emitting display apparatus according to claim 1, wherein the electron injection layer comprises ytterbium and lithium fluoride and the electron injection layer in the corner region has a ratio of ytterbium to lithium fluoride of 1:2 or 1:3.

6. The light emitting display apparatus according to claim 1, wherein the electron injection layer comprises ytterbium and lithium fluoride and the electron injection layer in the side region has a ratio of ytterbium to lithium fluoride of 3:1.

7. A light emitting display apparatus comprising:
a substrate having an active area and a non-active area that is disposed at an edge of the light emitting display apparatus, the non-active area surrounding a center area of the active area, a corner region of the active area, and a side region of the active area that excludes the center area;
a voltage line in the non-active area of on the substrate;
a thin-film transistor in a pixel area of the active area;
an anode on the thin-film transistor in the pixel area, the anode electrically connected to the thin-film transistor;
a connecting pattern on the voltage line, the connecting pattern electrically connected to the voltage line;
a bank having an emission open section that exposes a portion of the anode and a bank open section that exposes a portion of the connecting pattern;
an electron injection layer in the emission open section and the bank open section; and
a cathode on the electron injection layer,
wherein the electron injection layer has different thicknesses in the center area of the active area and the corner region.

8. The light emitting display apparatus according to claim 7, wherein a thickness of the electron injection layer in the corner region is thicker than a thickness of the electron injection layer in the center area of the active area.

9. The light emitting display apparatus according to claim 8, wherein the thickness of the electron injection layer in the center area is a same as a thickness of the electron injection layer in the side region.

10. The light emitting display apparatus according to claim 7, wherein the electron injection layer comprises ytterbium and lithium fluoride and the electron injection layer in the center area of the active area has a ratio of ytterbium to lithium fluoride of 2:1.

11. The light emitting display apparatus according to claim 7, wherein the electron injection layer comprises ytterbium and lithium fluoride and the electron injection layer in the corner region has a ratio of ytterbium to lithium fluoride of 1:2 or 1:3.

12. The light emitting display apparatus according to claim 7, wherein the electron injection layer comprises ytterbium and lithium fluoride and the electron injection layer in the side region has a ratio of ytterbium to lithium fluoride of 3:1.

13. The light emitting display apparatus according to claim 7, further comprising:
a hole injection layer, a hole transport layer, an emission layer, and an electron transport layer between the anode and the electron injection layer in the emission open section.

14. The light emitting display apparatus according to claim 7, wherein the voltage line and the thin-film transistor are on a same layer, the light emitting display apparatus further comprising:
a first planarization layer and a second planarization layer between the voltage line and the thin-film transistor and the anode,
a first connecting metal pattern between the first planarization layer and the second planarization layer, the first connecting metal pattern electrically connecting the thin-film transistor and the anode, and
a second connecting metal pattern between the first planarization layer and the second planarization layer, the second connecting metal pattern electrically connecting the voltage line and the connecting pattern.

15. A display device comprising:
a substrate having an active area and a non-active area that surrounds the active area, the active area including a center area and a corner area;
a plurality of thin-film transistors including a first thin-film transistor and a second thin-film transistor;
a first light-emitting diode in the center area that is electrically connected to the first thin-film transistor, the first light-emitting diode including a first anode electrode, a first organic emission layer on the first anode electrode that includes a first electron injection layer, and a cathode electrode on the first organic emission layer; and
a second light-emitting diode in the corner area that is electrically connected to the second thin-film transistor, the second light-emitting diode including a second anode electrode, a second organic emission layer on the second anode electrode that includes a second electron injection layer, and a second cathode electrode on the second organic emission layer,
wherein a thickness of the first electron injection layer is different than a thickness of the second electron injection layer.

16. The display device of claim 15, wherein the thickness of the second electron injection layer is thicker than the thickness of the first electron injection layer.

17. The display device of claim 15, wherein the plurality of thin-film transistors includes a third thin film transistor and the display device further comprises:
a third light-emitting diode that is electrically connected to the third thin film transistor and disposed in a side area of the active area that is between a pair of corner areas of the active area, the third thin film transistor including a third anode electrode, a third organic emission layer on the third anode electrode that includes a third electron injection layer, and a third cathode electrode on the third organic emission layer,
wherein a thickness of the first electron injection layer is a same as a thickness of the third electron injection layer.

18. The display device of claim 17, wherein the first electron injection layer comprises ytterbium and lithium fluoride having a ratio of ytterbium to lithium fluoride of 2:1 and wherein the second electron injection layer comprises ytterbium and lithium fluoride having a ratio of ytterbium to lithium fluoride of 1:2 or 1:3.

19. The display device of claim 18, wherein the third electron injection layer comprises ytterbium and lithium fluoride having a ratio of ytterbium to lithium fluoride of 3:1.

20. The display device of claim 15, further comprising:
a voltage line in the non-active area; and
a third organic emission layer that overlaps the voltage line in the non-active area, the third organic emission layer having a third electron injection layer but does not include a hole injection layer, a hole transport layer, an emission layer, and an electron transport layer.
